(19) United States
(12) Patent Application Publication
(10) Pub. No.: US 2026/0276673 A1
(43) Pub. Date: Sep. 17, 2026

(54) PROBE MODULE AND MICROPROBE SYSTEM COMPRISING SAME

(71) Applicant: NEXTRON CORPORATION, Busan (KR)

(72) Inventors: Hak Beom MOON, Gyeongsang-nam-do (KR); Yun Hyeong JANG, Busan (KR); Ji Su SEONG, Busan (KR)

(21) Appl. No.: 19/153,734

(22) PCT Filed: Feb. 7, 2023
(86) PCT No.: PCT/KR2023/001721

§ 371 Date: Aug. 5, 2025

(51) Int. Cl. G01R 1/04; G01R 1/067

(52) U.S. Cl. CPC G01R 1/04; G01R 1/06744

(57) ABSTRACT

A probe module includes: a base; a guide rail which is provided on the base; a guide member which slides along the guide rail; a rotating member which is connected to the guide member to be rotatable with respect to the guide member about a first axis parallel to the height direction; a probe assembly which is connected to the rotating member to be rotatable with respect to the rotating member about a second axis perpendicular to the first axis in a first horizontal rotation direction approaching toward a specimen and a second horizontal rotation direction away from the specimen, and includes a probe; and an elastic member which provides torque to the probe assembly in the first horizontal rotation direction.

### CROSS REFERENCE TO RELATED PATENT APPLICATIONS

This is a U.S. national phase patent application of PCT/KR2023/001721 filed Feb. 7, 2023, the entire contents of which are incorporated herein by reference for all purposes.

### TECHNICAL FIELD

The description below relates to a probe module and a microprobe system including the same.

### BACKGROUND ART

In the semiconductor manufacturing process, it is necessary to inspect the material characteristics of solid-liquid specimens formed on a wafer or a base substrate, such as electromagnetic, dielectric, optical, and chemical characteristics. Since the device characteristics are affected by external factors, it is necessary to provide a vacuum state or an environment in which light irradiation, gas, temperature, and humidity are controlled in the process of detecting the device characteristics.

To detect a characteristic of a specimen, a microprobe system that provides a chamber inside which the specimen is disposed is provided. In general, a microprobe system detects a characteristic of a device through a probe that contacts the device. Accordingly, a microprobe system including a probe module that may move precisely is required.

The above description is information the inventor(s) acquired during the course of conceiving the present disclosure, or already possessed at the time, and was not necessarily publicly known before the present application was filed.

### SUMMARY

An object according to an embodiment is to provide a probe module of which a position is precisely controlled.

An object according to an embodiment is to provide a probe module of which a position is easily controlled.

An object according to an embodiment is to provide a probe module with a low production cost.

An object according to an embodiment is to provide a probe module capable of maintaining contact with a specimen with uniform force.

A probe module according to an embodiment includes a base, a guide rail installed on the base, a guide member configured to slide along the guide rail, a rotating member rotatably connected to the guide member with respect to the guide member around a first axis that is parallel to a height direction, a probe assembly including a probe and rotatably connected to the rotating member with respect to the rotating member in a first horizontal rotation direction toward a specimen and a second horizontal rotation direction away from the specimen around a second axis that is perpendicular to the first axis, and an elastic member configured to provide torque to the probe assembly in a first horizontal rotation direction.

The elastic member may be positioned between a rotating member and a probe assembly.

The elastic member may include a compression spring disposed further than the second axis based on a distance from an end portion of the probe.

The elastic member may include a tension spring disposed closer than the second axis based on a distance from an end portion of the probe.

The probe assembly may further include a probe housing connected to the rotating member and enclosing at least a portion of the probe.

The probe housing may include a separation prevention pin configured to prevent separation of the elastic member.

The probe module may further include a gripping portion extending from the probe housing toward an end portion of the probe to facilitate gripping when the probe module rotates in a second horizontal rotation direction.

An uneven portion may be formed on at least a portion of the gripping portion.

The probe may include an exposed portion exposed to an outside of the housing and a carry-in portion carried into the housing, in which the carry-in portion may include at least one bent portion, and the probe housing may include an accommodating groove recessed in a shape corresponding to the carry-in portion to accommodate at least a portion of the carry-in portion.

The probe module may further include one or more stoppers configured to limit a rotation angle of the probe assembly in at least one of the first horizontal rotation direction and the second horizontal rotation direction.

A microprobe system according to an embodiment may include the probe module.

*21A probe module according to an embodiment may accurately measure a characteristic of a specimen.

A probe module according to an embodiment may easily measure a characteristic of a specimen.

A probe module according to an embodiment may be manufactured at a low cost.

The effects of the probe module and the microprobe system including the same according to an embodiment may not be limited to the above-mentioned effects, and other unmentioned effects may be clearly understood from the following description by one of ordinary skill in the art.

### BRIEF DESCRIPTION OF DRAWINGS

The accompanying drawings illustrate preferred embodiments of the present disclosure, and are provided together with the detailed description for better understanding of the technical idea of the present disclosure. Therefore, the present disclosure should not be construed as being limited to the embodiments set forth in the drawings.

FIG. 1 is a perspective view of a microprobe system according to an embodiment.

FIG. 2 is a plan view in which a state in which a second housing is open in a microprobe system is viewed from an upper surface, according to an embodiment.

FIG. 3 is a perspective view of a probe module according to an embodiment.

FIG. 4 is an exploded perspective view of a guide member and a rotating member, according to an embodiment.

FIGS. 5A to 5C are plan views in which a probe module is viewed from a side surface, according to an embodiment.

FIG. 6 is an exploded perspective view of a probe assembly according to an embodiment.

FIG. 7 is a perspective view of a probe module according to an embodiment.

### DESCRIPTION OF AN EMBODIMENT

Hereinafter, embodiments will be described in detail with reference to the accompanying drawings. However, various alterations and modifications may be made to the embodiments and thus, the scope of the disclosure is not limited or restricted to the embodiments. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In the descriptions of the embodiments referring to the accompanying drawings, like reference numerals refer to like elements and any repeated description related thereto will be omitted. In the description of embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the embodiments. Each of these terms is not used to define an essence, order, or sequence of corresponding components, but used merely to distinguish the corresponding components from other components. It is to be understood that if a component is described as being “connected,” “coupled” or “joined” to another component, the former may be directly “connected,” “coupled,” and “joined” to the latter or “connected”, “coupled”, and “joined” to the latter via another component.

Components included in an embodiment and components having a common function are described using the same names in other embodiments. Unless stated otherwise, the description of an embodiment may be applicable to other embodiments, and a repeated description related thereto is omitted.

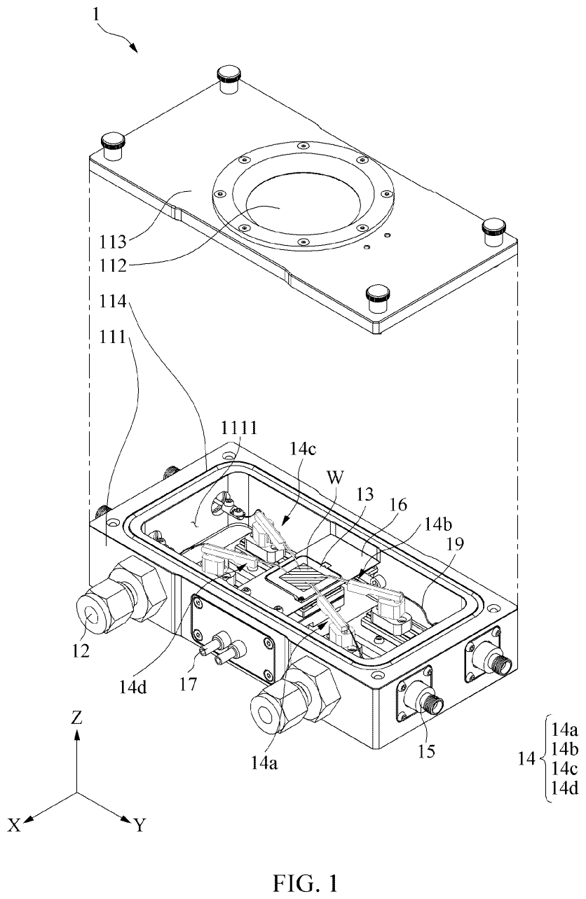

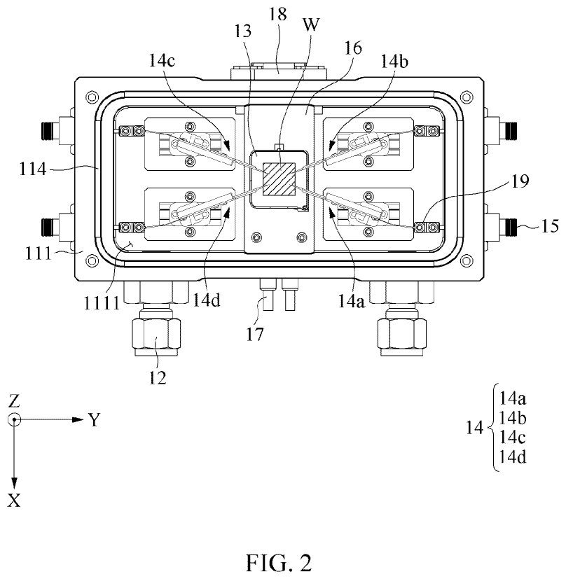

FIG. 1 is a perspective view of a microprobe system according to an embodiment, and FIG. 2 is a plan view in which a state in which a second housing is open in a microprobe system is viewed from an upper surface, according to an embodiment.

Referring to FIGS. 1 and 2, a microprobe system 1 according to an embodiment may detect a material characteristic of a specimen W. The specimen W may be, for example, a semiconductor device formed on a wafer. In FIGS. 1 and 2, the specimen W is shown as a quadrangle for convenience, but this is an example for ease of description and may be various types of semiconductor devices formed on the wafer. The microprobe system 1 may detect various characteristics of the specimen W, for example, an electrical characteristic, an optical characteristic, and a chemical characteristic, by interoperating with other devices. The microprobe system 1 according to an embodiment may include a housing 11, a vacuum port 12, an observation stage 13, a probe module 14, a signal port 15, a support 16, a temperature controller, a cooler 17, a power port 18, and a power connector 19.

In an embodiment, the housing 11 may form the exterior of the microprobe system 1. In an embodiment, the housing 11 may include a first housing 111, a second housing 112, a window 113, and a sealing member 114.

In an embodiment, the first housing 111 may have one side formed to be open and may provide an inspection space 1111 to inspect the characteristic of the specimen W. For example, an upper portion of the first housing 111 may be formed to be open. For example, the inspection space 1111 may have a volume of 100 cc or less. According to this structure, to inspect the specimen W, the process of forming the inspection space 1111 in a vacuum state or purging gas into the inspection space 1111 may be performed quickly. Accordingly, the microprobe system 1 may accurately measure the characteristic of the specimen W, even when the characteristic of the specimen W is sensitive to the surrounding environment.

In an embodiment, the second housing 112 may be connected to one side of the first housing 111 so that the inspection space 1111 is sealed. For example, the second housing 112 may be connected to the open upper portion of the first housing 111. The second housing 112 may maintain a vacuum state or a gas purge state of the inspection space 1111 by sealing the inspection space 1111. The second housing 112 may be provided with a fixing screw that may be fixedly coupled to the first housing 111. The fixing screw may be provided, for example, at an outer edge of the second housing 112 and may be coupled to a fixing groove formed in an upper surface of the first housing 111.

In an embodiment, the window 113 may be formed of a transparent material so that the inspection space 1111 is viewed from the outside of the housing 11. The window 113 may be formed of a material such as, for example, quartz, sapphire, glass, tempered glass, or acrylic. With this structure, a method of detecting the optical characteristic of the specimen W may be performed by irradiating light through the window 113 from the outside of the inspection space 1111, and conversely, the optical characteristic of the specimen W may be detected by inputting an electrical signal. For example, the window 113 may be arranged on one side of the second housing 112. However, this is an example, and the arrangement of the window 113 is not limited thereto.

In an embodiment, the sealing member 114 may seal the gap between the first housing 111 and the second housing 112 when the second housing 112 is connected to the first housing 111. The sealing member may be arranged in at least one of the upper surface of the first housing 111 and a lower surface of the second housing 112 along the periphery of the inspection space 1111. Accordingly, the sealing member 114 may assist in sealing the inspection space 1111.

In an embodiment, the vacuum port 12 may be formed through the housing 11 so that a vacuum is formed in the inspection space 1111. In an embodiment, the vacuum port 12 may be connected to an exhaust line, thereby serving as a path for exhausting gas from the inspection space 1111. In an embodiment, the vacuum port 12 may be connected to an external device, thereby serving as a path for removing air from the inspection space 1111. Furthermore, the vacuum port 12 may inject gas and moisture into the inspection space 1111 by being connected to the external device. In the process of detecting at least one of electrical, optical, dielectric, magnetic, and chemical characteristics of the specimen W, when gas and moisture are injected into the inspection space 1111, the vacuum port 12 may serve as a path for injecting the gas. In an embodiment, the vacuum port 12 may be provided in plurality. For example, two vacuum ports 12 may be arranged on one side of the first housing 111. However, this is an example, and the number and arrangement of the vacuum ports 12 are not limited thereto.

In an embodiment, the observation stage 13 may be arranged in the inspection space 1111, and the specimen W to be inspected may be seated. In an embodiment, the observation stage 13 may be positioned at a center portion of the inspection space 1111.

In an embodiment, the probe module 14 may be arranged in the inspection space 1111 and may detect various characteristics of the specimen W by contacting the specimen W. In an embodiment, the probe module 14 may be arranged around the observation stage 13. In an embodiment, the probe module 14 may be provided in plurality and may simultaneously detect electrical characteristics of a plurality of points of the specimen W. For example, the probe module 14 may include a first probe module 14a, a second probe module 14b, a third probe module 14c, and a fourth probe module 14d. For example, each of the four probe modules 14 may be arranged to surround the observation stage 13 and may contact the specimen W at the four different points.

In an embodiment, the signal port 15 may be formed through the housing 11 to connect a signal line for transmitting and receiving an electrical signal from the probe module 14. For example, the signal port 15 may be arranged on one side of the first housing 111. In an embodiment, the signal port 15 may be provided in a number corresponding to the number of probe modules 14. For example, when the probe module 14 is provided in group of four, the signal port 15 may be provided in group of four. However, this is an example, and the number and arrangement of the signal ports 15 are not limited thereto.

In an embodiment, the support 16 may support the observation stage 13 from the housing 11. For example, the support 16 may support the observation stage 13 with respect to the first housing 111. In an embodiment, a support space may be formed in a lower portion of the support 16. For example, the temperature controller and the cooler 17 described below may be disposed in the support space.

In an embodiment, the temperature controller may control the temperature of the specimen W. In an embodiment, the temperature controller may include a thermoelectric element formed of a Peltier element, a resistance heater, and various heat exchange devices. For example, the temperature controller may control the temperature of the specimen W within a range of −40 degrees or more to 150 degrees or less. However, this is an example, and the range for controlling the temperature of the specimen W is not limited thereto. For example, the temperature controller may control the temperature of the specimen W within a range of 80K or more to 373K or less.

In an embodiment, the cooler 17 may cool the temperature controller. In an embodiment, heat may be generated in the process of the temperature controller controlling the temperature of the specimen W, and the cooler 17 may dissipate the heat generated in the temperature controller. The cooler 17 may be supported by the first housing 111.

In an embodiment, the power port 18 may be formed through the housing 11 to supply power to the microprobe system 1. For example, the power port 18 may be arranged on one side of the first housing 111. For example, the power port 18 may be electrically connected to the temperature controller to supply power to the temperature controller. However, this is an example, and the arrangement of the power port 18 and the power supply target are not limited thereto.

In an embodiment, the power connector 19 may be connected to the other side of a probe 1451, for example, a contact portion of the probe 1451 so that electricity is applied to the probe 1451. The power connector 19 may be connected to the signal port 15, thereby applying electricity to the specimen W through the probe 1451 or transmitting the electrical characteristic of the specimen W to an external signal line.

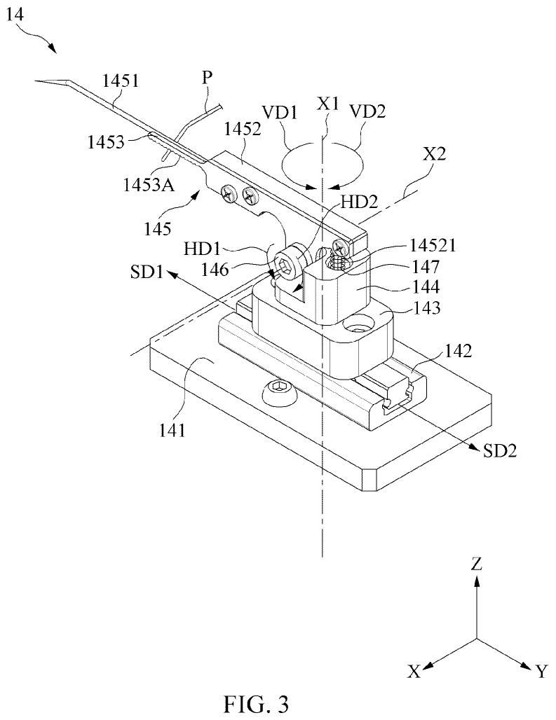

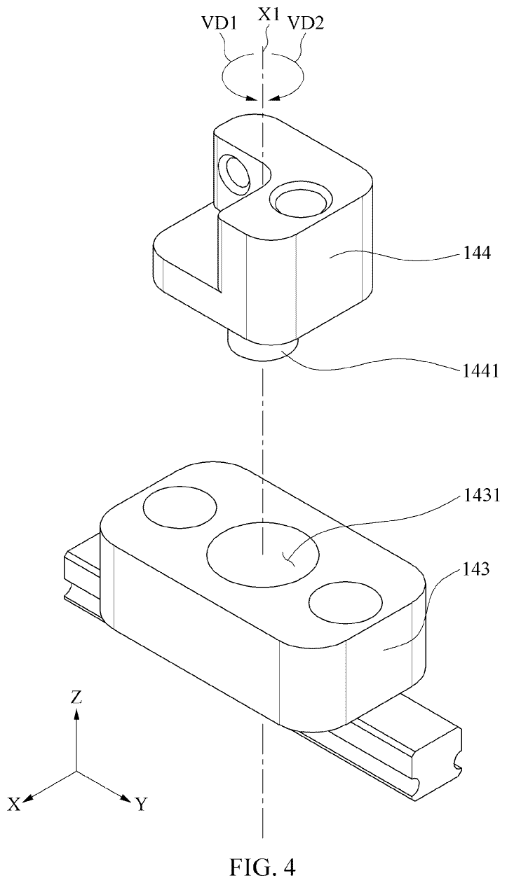

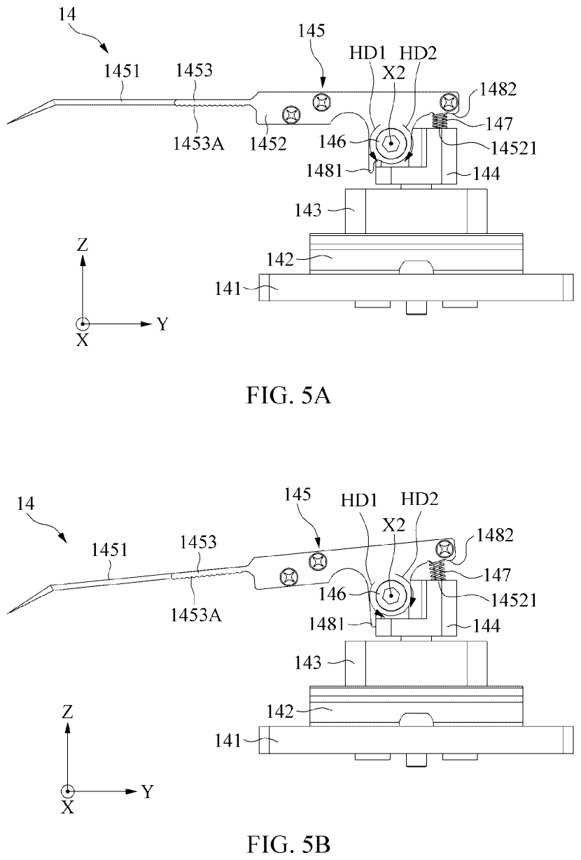

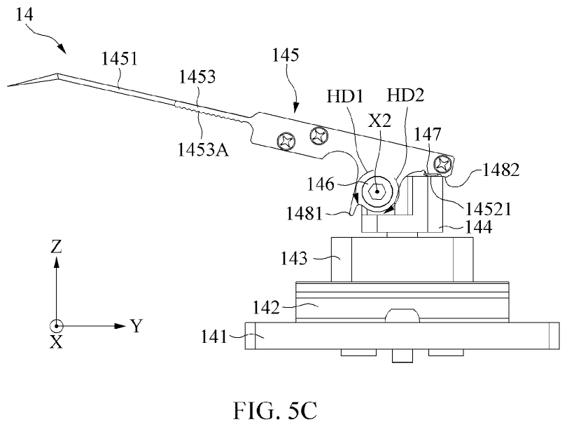

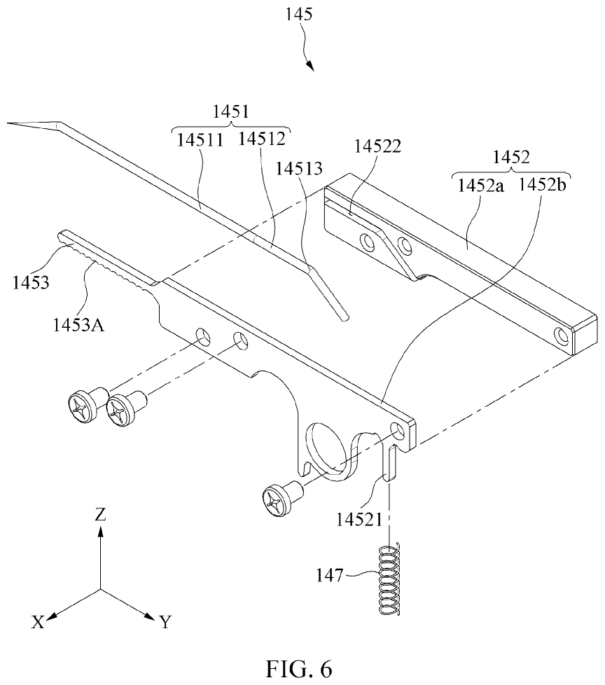

FIG. 3 is a perspective view of a probe module according to an embodiment, FIG. 4 is an exploded perspective view of a guide member and a rotating member, according to an embodiment, and FIGS. 5A to 5C are plan views in which a probe module is viewed from a side surface, according to an embodiment, and FIG. 6 is an exploded perspective view of a probe assembly according to an embodiment.

Referring to FIGS. 3 to 5C, the probe module 14 according to an embodiment may include a base 141, a guide rail 142, a guide member 143, a rotating member 144, a probe assembly 145, a connector 146, an elastic member 147, and a stopper 148.

The base 141 may be installed on the bottom of the inspection space 1111 of the housing 11. A through hole formed by penetrating along a vertical direction may be formed in the base 141, and a screw may be inserted into the through hole, thereby fixing the base 141 to the bottom of the inspection space 1111 of the housing 11.

In an embodiment, the guide rail 142 may be installed on an upper surface of the base 141, and the guide member 143 may slide along the guide rail 142 in a first sliding direction SD1 and/or a second sliding direction SD2. For example, the guide rail 142 may be an LM guide. The guide member 143 may move in a direction of or away from the observation stage 13 while sliding along the guide rail 142. As a result, it may be possible to adjust the distance of the probe assembly 145 in a horizontal direction with respect to the specimen W through the movement of the guide member 143.

For example, the rotating member 144 may be rotatably connected to the guide member 143 with respect to the guide member 143 around a first axis X1 that is parallel to a height direction. For example, as shown in FIG. 4, a shaft 1441 may protrude from one side of the rotating member 144, and a shaft groove 1431 may be recessed from one side of the guide member 143 in a shape corresponding to the shaft 1441. For example, the shaft 1441 of the rotating member 144 may be mounted on the shaft groove 1431 of the guide member 143, and the rotating member 144 may rotate with respect to the guide member 143 in a first vertical rotation direction VD1 and/or a second vertical rotation direction VD2 around the shaft 1441. In this structure, in FIG. 3, the probe assembly 145 may rotate with respect to the base 141 around the first axis X1.

In an embodiment, around a second axis X2 that is perpendicular to the first axis X1, the probe assembly 145 may be rotatably connected to the rotating member 144 with respect to the rotating member 144 in a first horizontal rotation direction HD1 toward the specimen W and a second horizontal rotation direction HD2 away from the specimen W. For example, a connecting groove may be formed through a probe housing 1452 described below and the rotating member 144 in a direction parallel to the second axis X2, and the connector 146 may connect the rotating member 144 to the probe assembly 145 by penetrating the connecting groove.

In an embodiment, the elastic member 147 may provide torque to the probe assembly 145 in the first horizontal rotation direction HD1. For example, the elastic member 147 may be positioned between the rotating member 144 and the probe assembly 145 and may connect the rotating member 144 to the probe assembly 145. For example, a groove for accommodating the elastic member 147 may be formed on one side of the rotating member 144. In an embodiment, the elastic member 147 may include a compression spring. For example, the elastic member 147 including the compression spring may be disposed further than the second axis X2 based on the distance from an end portion of the probe 1451 described below. In this structure, with the specimen W positioned on the observation stage 13, the probe assembly 145 may maintain contact with the specimen W by applying continuous external force to the specimen W.

In an embodiment, the stopper 148 may limit the rotation angle of the probe assembly 145 in at least one of the first horizontal rotation direction HD1 and the second horizontal rotation direction HD2. In an embodiment, as shown in FIG. 5A, the stopper 148 may include a first stopper 1481 limiting the rotation angle of the probe assembly 145 in the first horizontal rotation direction HD1 and a second stopper 1482 limiting the rotation angle of the probe assembly 145 in the second horizontal rotation direction HD2. For example, each of the first stopper 1481 and the second stopper 1482 may protrude from one side of the probe housing 1452 described below. In this structure, as shown in FIG. 5B, when the probe assembly 145 is rotated by a specified angle in the first horizontal rotation direction HD1, the first stopper 1481 and the rotating member 144 may contact each other, thereby preventing the probe assembly 145 from rotating in the first horizontal rotation direction HD1 beyond the specified angle. As shown in FIG. 5C, when the probe assembly 145 is rotated by a specified angle in the second horizontal rotation direction HD2, the second stopper 1482 and the rotating member 144 may contact each other, thereby preventing the probe assembly 145 from rotating in the second horizontal rotation direction HD2 beyond the specified angle.

Referring to FIGS. 3 and 6, the probe assembly 145 according to an embodiment may include the probe 1451, the probe housing 1452, and a gripping portion 1453.

In an embodiment, the probe 1451 may have a longitudinal direction, have a pointy end portion, and contact the specimen W. For example, the end portion of the probe 1451 may be formed to be bent at a specified angle toward the specimen W based on the longitudinal direction of the probe 1451. In an embodiment, the probe 1451 may include an exposed portion 14511 exposed to the outside of the probe housing 1452 and a carry-in portion 14512 carried into the probe housing 1452, which are described below.

In an embodiment, the probe housing 1452 may enclose 11 at least a portion of the probe 1451. In an embodiment, the probe housing 1452 may include a first probe housing 1452a and a second probe housing 1452b. For example, the first probe housing 1452a and the second probe housing 1452b may be connected to each other with the probe 1451 therebetween.

In an embodiment, the carry-in portion 14512 of the probe 1451 may include at least one bent portion 14513. For example, the carry-in portion 14512 may be bent by an angle specified in the bent portion 14513. In an embodiment, the probe housing 1452 may include an accommodating groove 14522 recessed in a shape corresponding to the carry-in portion 14512. For example, the accommodating groove 14522 may be formed to be bent to correspond to the bent portion 14513 of the probe 1451 on one side of the second housing 112. In an embodiment, the accommodating groove 14522 may accommodate at least a portion of the carry-in portion 14512 of the probe 1451. For example, the carry-in portion 14512 of the probe 1451 may be accommodated in the accommodating groove 14522 formed in the second housing 112, and the first housing 111 may be coupled to a surface of the second housing 112 in which the accommodating groove 14522 is formed. In this structure, it may be possible to prevent the probe 1451 from rotating by taking the longitudinal direction as an axis while being accommodated in the probe housing 1452.

In an embodiment, a length in the longitudinal direction of the probe 1451 may be decreased depending on the shape of the probe housing 1452. The probe 1451 may generally be more expensive than the probe housing 1452. To reduce the manufacturing cost of the probe assembly 145, the length in the longitudinal direction of the probe 1451 may be formed to be short in a manner that the length in the longitudinal direction of the probe 1451 is increased.

Referring to FIGS. 3, 5A, and 6, the probe assembly 145 according to an embodiment may further include the gripping portion 1453, and the probe housing 1452 may further include a separation prevention pin 14521.

In an embodiment, the gripping portion 1453 may extend from one side of the housing 11 toward the end portion of the probe 1451 in the longitudinal direction of the probe 1451. For example, the gripping portion 1453 may extend from one side of the first housing 111. For example, when viewed in a direction parallel to the second axis X2, at least a portion of the gripping portion 1453 and at least a portion of the probe 1451 may overlap. In an embodiment, a gripping part 1453A may be formed in at least a portion of the gripping portion 1453 to facilitate gripping when the probe module 14 rotates in the second horizontal rotation direction HD2. For example, the probe assembly 145 may rotate in the second horizontal rotation direction HD2 when tweezers P make contact with the gripping part 1453A to sit the specimen W on the observation stage 13. In an embodiment, a structure for preventing the tweezers P from slipping may be formed in the gripping part 1453A. For example, an uneven portion may be formed in the gripping part 1453A. However, this is an example, and the structure of the gripping part 1453A is not limited thereto. For example, the gripping part 1453A may be formed of a flat but high-friction material.

In an embodiment, the separation prevention pin 14521 may prevent the separation of the elastic member 147. In an embodiment, the separation prevention pin 14521 may extend from one side of the housing 11 to a direction toward the rotating member 144 to have a longitudinal direction. For example, the separation prevention pin 14521 may extend from one side of the first housing 111 and be disposed further than the second axis X2 based on the distance from the end portion of the probe 1451. In an embodiment, the elastic member 147 may be wound around the separation prevention pin 14521 while connecting the rotating member 144 to the probe assembly 145. In this structure, it may be possible to prevent the elastic member 147 from being separated from the probe assembly 145 while being accommodated in the groove formed in the rotating member 144.

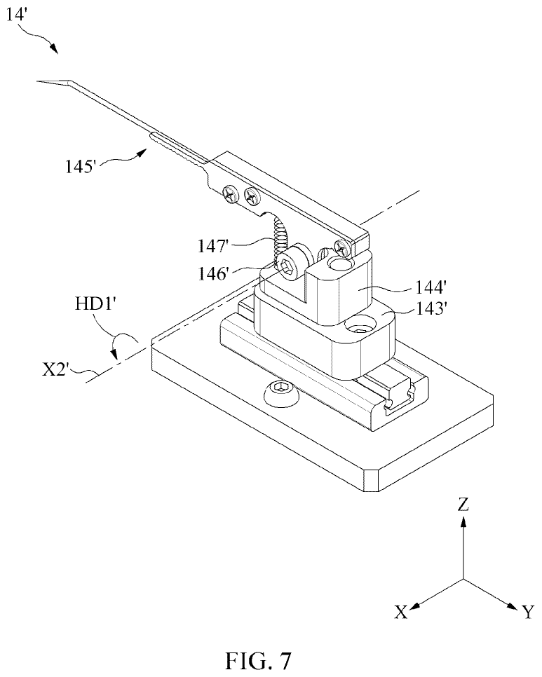

FIG. 7 is a perspective view of a probe module according to an embodiment.

Referring to FIG. 7, a probe module 14′ according to an embodiment may include a guide member 143′, a rotating member 144′, a probe assembly 145′, a connector 146′, and an elastic member 147′.

The guide member 143′, the rotating member 144′, the probe assembly 145′, and the connector 146′ of FIG. 7 are substantially the same as the guide member 143, the rotating member 144, the probe assembly 145, and the connector 146 described with reference to FIGS. 1 to 6, and thus, a detailed description thereof is omitted. In addition, for ease of description, in describing the probe module 14′ of FIG. 7, a detailed description of the contents overlapping the probe module 14 described with reference to FIGS. 1 to 6 is omitted.

In an embodiment, the elastic member 147′ may provide torque to the probe assembly 145′ in a first horizontal rotation direction HD1′ around the second axis X2. For example, the elastic member 147′ may be positioned between the rotating member 144′ and the probe assembly 145′ and may connect the rotating member 144′ to the probe assembly 145′. For example, a ring may be formed in both end portions of the elastic member 147′, and the ring formed in one end portion of the elastic member 147′ may be caught by the probe assembly 145′, and the ring formed in the other end portion may be caught by the rotating member 144′. In an embodiment, the elastic member 147′ may include a tension spring. For example, the elastic member 147′ including the tension spring may be disposed closer than the second axis based on the distance from an end portion of a probe. In this structure, with a specimen positioned on an observation stage, the probe assembly 145′ may maintain contact with the specimen by applying continuous external force to the specimen.

Although the embodiments have been described with reference to the limited drawings, one of ordinary skill in the art may apply various technical modifications and variations based thereon. For example, suitable results may be achieved if the described techniques are performed in a different order, and/or if components in a described system, architecture, device, or circuit are combined in a different manner, or replaced or supplemented by other components or their equivalents.

Accordingly, other implementations are within the scope of the following claims.

1. A probe module comprising:
a base;
a guide rail installed on the base;
a guide member configured to slide along the guide rail;
a rotating member rotatably connected to the guide member with respect to the guide member around a first axis that is parallel to a height direction;
a probe assembly further comprising a probe and rotatably connected to the rotating member with respect to the rotating member in a first horizontal rotation direction toward a specimen and a second horizontal rotation direction away from the specimen around a second axis that is perpendicular to the first axis; and
an elastic member configured to provide torque to the probe assembly in the first horizontal rotation direction.

2. The probe module of claim 1, wherein the elastic member is positioned between the rotating member and the probe assembly.

3. The probe module of claim 2, wherein the elastic member further comprises a compression spring disposed further than the second axis based on a distance from an end portion of the probe.

4. The probe module of claim 2, wherein the elastic member further comprises a tension spring disposed closer than the second axis based on a distance from an end portion of the probe.

5. The probe module of claim 1, wherein the probe assembly further comprises a probe housing connected to the rotating member and enclosing at least a portion of the probe.

6. The probe module of claim 5, wherein the probe housing further comprises a separation prevention pin configured to prevent separation of the elastic member.

7. The probe module of claim 6, further comprising:
a gripping portion extending from the probe housing toward an end portion of the probe to facilitate gripping when the probe assembly rotates in the second horizontal rotation direction.

8. The probe module of claim 7, wherein an uneven portion is formed on at least a portion of the gripping portion.

9. The probe module of claim 6, wherein the probe further comprises an exposed portion exposed to an outside of the probe housing and a carry-in portion carried into the probe housing, wherein the carry-in portion comprises at least one bent portion, wherein the probe housing further comprises an accommodating groove recessed in a shape corresponding to the carry-in portion to accommodate at least a portion of the carry-in portion.

10. The probe module of claim 1, further comprising:
one or more stoppers configured to limit a rotation angle of the probe assembly in at least one of the first horizontal rotation direction and the second horizontal rotation direction.

11. A microprobe system comprising:
the probe module according to claim 1.
